(19) United States
(12) Patent Application Publication
(10) Pub. No.: US 2023/0215972 A1
(43) Pub. Date: Jul. 6, 2023

(54) Epitaxial Wafer of Red Light-Emitting Diode, and Preparation Method Therefor

(71) Applicant: CHONGQING KONKA PHOTOELECTRIC TECHNOLOGY RESEARCH INSITUTE CO., LTD., Chongqing (CN)

(72) Inventors: Wenyang HUANG, Chongqing (CN); Ya-Wen LIN, Chongqing (CN); Kuo-Tung HUANG, Chongqing (CN); Chia-Hung HUANG, Chongqing (CN)

(21) Appl. No.: 17/433,231

(22) PCT Filed: Sep. 16, 2020
(86) PCT No.: PCT/CN2020/115675

§ 371 Date: Aug. 23, 2021

(30) Foreign Application Priority Data
Apr. 2, 2020 (CN) 202010255943.4

(51) Int. Cl. H01L 33/06; H01L 33/30; H01L 33/10; H01L 33/00; H01L 33/14; H01L 33/12

(52) U.S. Cl. CPC H01L 33/06; H01L 33/30; H01L 33/10; H01L 33/0062; H01L 33/14; H01L 33/12

(57) ABSTRACT

The present application provides an epitaxial wafer of a red light-emitting diode, and a preparation method therefor, by designing an n-type semiconductor layer as a gradient layer with the content of an aluminum element gradually increasing along a growth direction of the epitaxial wafer and the content of an indium element gradually decreasing along a stacking direction of the epitaxial wafer, and a constant layer with the content of an aluminum element and an indium element not changing along the growth direction of the epitaxial wafer, the potential barrier at the side close to a multi-quantum well layer gradually rises, preventing electrons and holes in the multi-well quantum layer for radiative recombination from moving to the outside of the MQW region, confining the holes and electrons to have a radiative recombination in the MQW and reducing non-radiative recombination, and also facilitating the flowing of electrons in the n-layer to the MQW region.

### TECHNICAL FIELD

The present application relates to the field of light-emitting diode preparation technologies, and in particular, to an epitaxial wafer of a red light-emitting diode, and a preparation method therefor.

### BACKGROUND

The existing epitaxial structure of a red light-emitting diode (LED) is mainly formed by growing, on a gallium arsenide (GaAs) substrate, an n-type GaAs buffer layer, an n-type distributed Bragg reflection (DBR) layer, an n-type confinement layer, a multi-quantum well (MQW) light-emitting layer, a p-type confinement layer, and a p-type gallium phosphide (GaP) current spreading layer. Wherein, the p-type confinement layer and the n-type confinement layer enable holes in the p-region and electrons in the n-region to realize recombination luminescence in the MQW region; however, a conventional p-type confinement layer and n-type confinement layer also block holes in the p-layer and electrons in the n layer from flowing to the MQW region when confining electrons and holes to recombine in the MQW region, thus affecting the light-emitting efficiency.

Accordingly, improvements and advancements still have to be made in the related art.

### SUMMARY

In view of the described deficiency of the related art, the objective of the present application is to provide an epitaxial wafer of a red light-emitting diode, and a preparation method therefor, aiming to solve the problem of low light-emitting efficiency of an existing red light-emitting diode.

The technical solutions of the present application are as follows:

An epitaxial wafer of a red light-emitting diode, comprising: an n-type semiconductor layer, a multi-quantum well layer and a p-type semiconductor layer that are sequentially stacked;

the n-type semiconductor layer comprises a first n-type confinement layer and a second n-type confinement layer;

the first n-type confinement layer comprises an aluminum element and an indium element, and the second n-type confinement layer comprises an aluminum element and an indium element; and in the first n-type confinement layer, the content of the aluminum element gradually increases along a growth direction of the epitaxial wafer, and the content of the indium element gradually decreases along the growth direction of the epitaxial wafer, and in the second n-type confinement layer, the content of the aluminum element and the indium element does not change along the growth direction of the epitaxial wafer.

Optionally, in the epitaxial wafer of a red light-emitting diode, the first n-type confinement layer is an n-type impurity doped AlₐIn₁₋ₐP layer, and the value of a gradually increases from 0.1 to x along the growth direction of the epitaxial wafer, wherein 0.3<x<0.7.

Optionally, in the epitaxial wafer of a red light-emitting diode, the second n-type confinement layer is an n-type impurity doped AlₓIn₁₋ₓP layer.

Optionally, in the epitaxial wafer of a red light-emitting diode, the first n-type confinement layer has a thickness of 40 nm-120 nm.

Optionally, in the epitaxial wafer of a red light-emitting diode, the thickness of the first n-type confinement layer is the same as the thickness of the second n-type confinement layer.

Optionally, in the epitaxial wafer of a red light-emitting diode, the p-type semiconductor layer comprises a first p-type confinement layer and a second p-type confinement layer that are sequentially stacked; the first p-type confinement layer comprises an aluminum element and an indium element, and the second p-type confinement layer comprises an aluminum element and an indium element; and in the first p-type confinement layer, the content of the aluminum element and the indium element does not change along the growth direction of the epitaxial wafer, and in the second p-type confinement layer, the content of the aluminum element gradually decreases along the growth direction of the epitaxial wafer, and the content of the indium element gradually increases along the growth direction of the epitaxial wafer.

Optionally, in the epitaxial wafer of a red light-emitting diode, the second p-type confinement layer is a p-type impurity doped Al_{b}In_{1-b}P layer, and the value of b gradually decreases from y to 0.1 along the growth direction of the epitaxial wafer, wherein 0.3<y<0.7.

Optionally, in the epitaxial wafer of a red light-emitting diode, the first p-type confinement layer is a p-layer of p-type impurity doped Al_{y}In_{1-y}R

Optionally, in the epitaxial wafer of a red light-emitting diode, the first n-type confinement layer has a thickness of 40 nm-120 nm.

Optionally, in the epitaxial wafer of a red light-emitting diode, the n-type semiconductor layer further comprises an n-type reflection layer, and the n-type reflection layer is an n-type Bragg reflection layer.

Optionally, in the epitaxial wafer of a red light-emitting diode, the epitaxial wafer further comprises a buffer layer and a current spreading layer, the buffer layer is stacked below the n-type semiconductor layer, and the current spreading layer is stacked above the p-type semiconductor layer.

A method for preparing an epitaxial wafer of a red light-emitting diode, wherein the method comprises:

providing a substrate; and

sequentially growing an n-type semiconductor layer, a multi-quantum well layer and a p-type semiconductor layer on a surface of the substrate;

wherein the n-type semiconductor layer comprises a first n-type confinement layer and a second n-type confinement layer that are sequentially stacked, and in the first n-type confinement layer, the content of an aluminum element gradually increases along a stacking direction of the epitaxial wafer, and the content of an indium element gradually decreases along the stacking direction of the epitaxial wafer, and in the second n-type confinement layer, the content of an aluminum element and an indium element does not change along the stacking direction of the epitaxial wafer.

Optionally, in the method for preparing an epitaxial wafer of a red light-emitting diode, growing an n-type semiconductor layer on a surface of the substrate specifically comprises:

controlling a molar flow rate of introduced gaseous aluminum to grow an n-type impurity doped AlₐIn₁₋ₐP layer on the buffer layer, the value of a gradually increasing from 0.1 to x along a growth direction of the epitaxial wafer, wherein 0.3<x<0.7; and

growing an n-type impurity doped AlₓIn₁₋ₓP layer on the n-type impurity doped AlₐIn₁₋ₐP layer.

Optionally, in the method for preparing an epitaxial wafer of a red light-emitting diode, the n-type impurity doped AlₓIn₁₋ₓP layer has a thickness of 40 nm-120 nm.

Optionally, in the method for preparing an epitaxial wafer of a red light-emitting diode, the n-type semiconductor layer further comprises an n-type reflection layer, and the n-type reflection layer is grown below the first n-type confinement layer.

Optionally, in the method for preparing an epitaxial wafer of a red light-emitting diode, the n-type reflection layer is an n-type Bragg reflection layer.

Optionally, a buffer layer is grown between the substrate and the n-type semiconductor layer, and a current spreading layer is grown above the p-type semiconductor layer.

Optionally, in the method for preparing an epitaxial wafer of a red light-emitting diode, the p-type semiconductor layer comprises a first p-type confinement layer and a second p-type confinement layer that are sequentially stacked; the first p-type confinement layer comprises an aluminum element and an indium element, and the second p-type confinement layer comprises an aluminum element and an indium element; and in the first p-type confinement layer, the content of the aluminum element and the indium element does not change along the growth direction of the epitaxial wafer, and in the second p-type confinement layer, the content of the aluminum element gradually decreases along the growth direction of the epitaxial wafer, and the content of the indium element gradually increases along the growth direction of the epitaxial wafer.

Optionally, in the method for preparing an epitaxial wafer of a red light-emitting diode, growing a p-type semiconductor layer on a surface of the multi-quantum well layer specifically comprises:

controlling a molar flow rate of introduced gaseous aluminum to grow a p-type impurity doped Al_{y}In_{1-y}P layer on the multi-quantum well layer, wherein 0.3<y<0.7; and

growing a p-layer of a p-type impurity doped Al_{b}In_{1-b}P layer on the p-type impurity doped Al_{y}In_{1-y}P layer, the value of b gradually decreasing from y to 0.1 along the growth direction of the epitaxial wafer.

Optionally, in the method for preparing an epitaxial wafer of a red light-emitting diode, the p-layer of p-type impurity doped Al_{y}In_{1-y}P has a thickness of 40 nm-120 nm.

The present application provides an epitaxial wafer of a red light-emitting diode, by designing an n-type semiconductor layer as a gradient layer (the first n-type confinement layer) with the content of an aluminum element gradually increasing along a growth direction of the epitaxial wafer and the content of an indium element gradually decreasing along a stacking direction of the epitaxial wafer, and a constant layer (the second n-type confinement layer) with the content of an aluminum element and an indium element not changing along the growth direction of the epitaxial wafer, the potential barrier at the side close to a multi-quantum well layer gradually rises, preventing electrons and holes in the multi-well quantum layer for radiative recombination from moving to the outside of the MQW region, confining the holes and electrons to have a radiative recombination in the MQW and reducing non-radiative recombination, and also facilitating the flowing of electrons in the n-layer to the MQW region, further increasing the number of photons flowing to the MQW region for recombination, thus improving the light-emitting efficiency.

### BRIEF DESCRIPTION OF THE DRAWINGS

FIG. 1 is a schematic diagram showing a structure of an epitaxial wafer of a red light-emitting diode provided in an embodiment of the present application.

FIG. 2 is a schematic diagram showing a structure of another epitaxial wafer of a red light-emitting diode provided in an embodiment of the present application.

FIG. 3 is a schematic diagram showing a structure of another epitaxial wafer of a red light-emitting diode provided in an embodiment of the present application.

FIG. 4 is a flowchart of a method for preparing an epitaxial wafer of a red light-emitting diode provided in an embodiment of the present application.

### DETAILED DESCRIPTION OF THE EMBODIMENTS

The present application provides an epitaxial wafer of a red light-emitting diode, and a preparation method therefor. To make the objective, technical solutions, and technical effects of the present application clearer and more definite, the present application is further described below with reference to the drawings and embodiments. It should be understood that the embodiments described herein are only intended to explain the present application, but not to limit the present application.

Sequential numbers of units herein, such as “first”, “second”, etc., are only used to distinguish the described objects and do not have any ordinal or technical meaning. The terms “connect” and “couple” used in the present application, unless specified otherwise, both include direct and indirect connection (coupling). In the description of the present application, it should be noted that the orientation or position relationships indicated by the terms “up”, “down”, “front”, “rear”, “left”, “right”, “vertical”, “horizontal”, “top”, “bottom”, “inner”, “outer”, “clockwise” and “counterclockwise” and the like are orientation or position relationships as shown in the drawings, which are only for the convenience of describing the present application and simplifying the description, rather than indicating or implying that the indicated device or element must have particular orientations, and must be constructed and operated in particular orientations, and thus should not be understood as limitations to the present application.

In the present application, unless specified or limited otherwise, a first feature “above” or “below” a second feature may mean that the first feature and the second feature are in direct contact, or that the first feature and the second feature are in indirect contact through an intermediate medium. Furthermore, a first feature “above”, “on” or “over” a second feature may mean that the first feature is right above or diagonally above the second feature, or just means that the first feature is at a level higher than the second feature. A first feature “below”, “under” or “underneath” a second feature may mean that the first feature is right below or diagonally below the second feature, or just means that the first feature is at a level lower than the second feature.

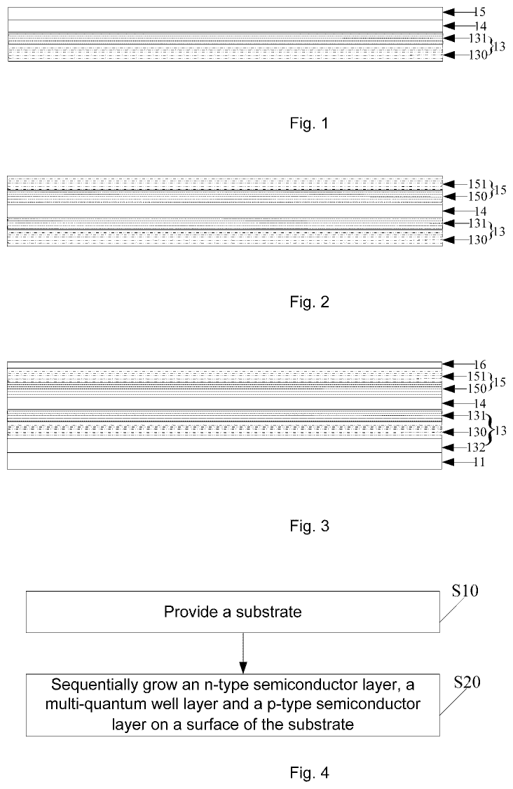

Please refer to FIG. 1, the epitaxial wafer of a red light-emitting diode provided in the present application comprises: an n-type semiconductor layer 13, a multi-quantum well layer 14 and a p-type semiconductor layer 15 that are sequentially stacked; the n-type semiconductor layer 13 comprises a first n-type confinement layer 130 and a second n-type confinement layer 131; the first n-type confinement layer 130 comprises an aluminum element and an indium element, and the second n-type confinement layer 131 comprises an aluminum element and an indium element; and in the first n-type confinement layer 130, the content of the aluminum element gradually increases along a growth direction of the epitaxial wafer, and the content of the indium element gradually decreases along the growth direction of the epitaxial wafer, and in the second n-type confinement layer 131, the content of the aluminum element and the indium element does not change along the growth direction of the epitaxial wafer.

In an existing epitaxial wafer of a red light-emitting diode, a conventional n-type confinement layer blocks the flowing of electrons in the n-layer to a multi-quantum well layer when confining electrons and holes in the multi-quantum well layer to recombine in the multi-quantum well region, affecting the number of electrons entering the multi-quantum well layer, and further affecting the light-emitting efficiency of the red light-emitting diode.

In order to solve the described problem, in the present embodiment, the n-type semiconductor layer is designed as a gradient confinement layer with the content of aluminum and indium elements gradually changing, and a confinement layer with the content of aluminum and indium elements being constant, and by providing a confinement layer of a certain thickness with the content of aluminum and indium elements being constant in a direction of the gradient confinement layer close to the multi-quantum well layer, a gradually rising potential barrier can be obtained so as to block holes and electrons in the multi-quantum well layer from moving to the outside, thus improving the light-emitting efficiency of the red light-emitting diode.

In one or more embodiments, the first n-type confinement layer is an n-type impurity doped AlₐIn₁₋ₐP layer, and the value of a gradually increases from 0.1 to x along the growth direction of the epitaxial wafer, wherein 0.3<x<0.7.

Specifically, in the n-type impurity doped AlₐInᵢ₋ₐP layer, the doped n-type impurity can be obtained by doping silane or diethyl telluride (DETe). The doping concentration of the process steps of doping implementation relate to the prior art, and will not be limited herein.

The content of Al element in the first n-type confinement layer gradually increases along the growth direction of the epitaxial wafer, for example, when starting to grow an n-type impurity doped AlₐInᵢ₋ₐP layer, the value of aluminum element component a is first set to be 0.1, and the value of aluminum element component a is gradually increased to x by gradually increasing the flow rate of the gaseous aluminum element for reaction, wherein the value of x may range from 0.3 to 0.5 or from 0.5 to 0.7. Setting the aluminum element component in the confinement layer to be 0.3 to 0.5 or 0.5 to 0.7 can confine the holes and electrons to have a radiative recombination in the multi-quantum well layer 14 and reduce non-radiative recombination; in addition, the potential barrier of the n-type confinement layer gradually rises, facilitating the flowing of electrons in the n-layer to the multi-quantum well layer 14 region, further increasing the number of photons flowing to the MQW region for recombination, thus improving the light-emitting efficiency.

In one or more embodiments, the second n-type confinement layer is an n-type impurity doped AlₓIn₁₋ₓP layer.

Specifically, after the growth of the n-type impurity doped AlₐIn₁₋ₐP layer is completed, an n-type impurity doped AlₓIn₁₋ₓP layer is continuously grown on a surface thereof, wherein the value of aluminum element component x may range from 0.3 to 0.7. That is, after the value of aluminum element component a in the n-type impurity doped AlₐIn₁₋ₐP layer is increased to a predetermined value, the flow rate of the gaseous aluminum element for reaction is controlled to be constant, and the n-type impurity doped AlₓIn₁₋ₓP layer of a certain thickness is grown on the n-type impurity doped AlₐIn₁₋ₐP layer. For example, if the value of a in the n-type impurity doped AlₐIn₁₋ₐP layer is gradually increased from 0.1 to 0.4 (Al_{0.4}In_{0.6}P), then Al_{0.4}In_{0.6}P or Al_{0.6}In_{0.4}P of a certain thickness is grown on a surface of the Al_{0.4}In_{0.6}P layer, and in this case, the n-type semiconductor layer is formed by stacking Al_{0.6}In_{0.4}P above the Al_{0.4}In_{0.6}P layer.

In one or more embodiments, the first n-type confinement layer may have a thickness of 40 nm to 50 nm, 50 nm to 60 nm, 60 nm to 70 nm, 70 nm to 80 nm, 80 nm to 90 nm, 90 nm to 100 nm, 100 nm to 110 nm or 110 nm to 120 nm.

In one or more embodiments, the second n-type confinement layer may have a thickness of 40 nm to 50 nm, 50 nm to 60 nm, 60 nm to 70 nm, 70 nm to 80 nm, 80 nm to 90 nm, 90 nm to 100 nm, 100 nm to 110 nm or 110 nm to 120 nm.

Setting the thicknesses of the first n-type confinement layer and the thicknesses of the second n-type confinement layer to be within the above ranges respectively may ensure the growth quality of the n-type confinement layers, thereby ensuring the overall quality of an epitaxial wafer of a red light-emitting diode.

It should be noted that, in a specific implementation, the thickness of the first n-type confinement layer may be the same as or different from the thickness of the second n-type confinement layer.

Please refer to FIG. 2, another epitaxial wafer of a red light-emitting diode is further provided in the present application, comprising: an n-type semiconductor layer 13, a multi-quantum well layer 14 and a p-type semiconductor layer 15 that are sequentially stacked; the n-type semiconductor layer 13 comprises a first n-type confinement layer 130 and a second n-type confinement layer 131; the first n-type confinement layer 130 comprises an aluminum element and an indium element, and the second n-type confinement layer 131 comprises an aluminum element and an indium element; and in the first n-type confinement layer 130, the content of the aluminum element gradually increases along a growth direction of the epitaxial wafer, and the content of the indium element gradually decreases along the growth direction of the epitaxial wafer, and in the second n-type confinement layer 131, the content of the aluminum element and the indium element does not change along the growth direction of the epitaxial wafer. The p-type semiconductor layer 15 comprises a first p-type confinement layer 150 and a second p-type confinement layer 151 that are sequentially stacked; the first p-type confinement layer 150 comprises an aluminum element and an indium element, and the second p-type confinement layer 151 comprises an aluminum element and an indium element; and in the first p-type confinement layer 150, the content of the aluminum element and the indium element does not change along the growth direction of the epitaxial wafer, and in the second p-type confinement layer 151, the content of the aluminum element gradually decreases along the growth direction of the epitaxial wafer, and the content of the indium element gradually increases along the growth direction of the epitaxial wafer.

In the present embodiment, the n-type semiconductor layer 13 is designed as a gradient layer (the first n-type confinement layer 130) with the content of an aluminum element gradually increasing along a growth direction of the epitaxial wafer and the content of an indium element gradually decreasing along a stacking direction of the epitaxial wafer, and a constant layer (the second n-type confinement layer 131) with the content of an aluminum element and an indium element not changing along the growth direction of the epitaxial wafer, and the p-type semiconductor layer 15 is designed as a constant layer (the first p-type confinement layer 150) with the content of an aluminum element and an indium element not changing along the growth direction of the epitaxial wafer, and a gradient layer (the second p-type confinement layer 151) with the content of an aluminum element gradually decreasing along the growth direction of the epitaxial wafer and the content of an indium element gradually increasing along the stacking direction of the epitaxial wafer, confining holes and electrons to have a radiative recombination in the multi-quantum well layer 14 and reducing non-radiative recombination; in addition, the design of enabling the potential barrier at two sides close to the multi-quantum well layer 14 to gradually rise (i.e., the potential barrier of the n-type confinement layer gradually increases along the growth direction of the epitaxial wafer and the potential barrier of the p-type confinement layer gradually decreases along the growth direction of the epitaxial wafer) also facilitates the flowing of electrons in the n-type semiconductor layer and holes in the p-type semiconductor layer to the multi-quantum well layer 14 region, further increasing the number of photons flowing to the multi-quantum well layer 14 region for recombination, thus improving the light-emitting efficiency.

In one or more embodiments, the second p-type confinement layer is a p-type impurity doped Al_{b}In_{1-b}P layer, and the value of b gradually decreases from y to 0.1 along the growth direction of the epitaxial wafer, wherein 0.3<y<0.7.

Specifically, in the p-type impurity doped Al_{b}In_{1-b}P layer, the p-type impurity may be obtained by doping Magnesocene (CP 2 Mg), tetrabromomethane (CBr 4) or diethyl zinc (DEZn). The doping concentration and the process steps of doping implementation relate to the prior art, and will not be limited herein.

Along the growth direction of the epitaxial wafer, in the first p-type confinement layer, the content of the aluminum element and the indium element does not change, that is to say, the aluminum element and the indium element in this layer are evenly distributed.

Along the growth direction of the epitaxial wafer, in the second p-type confinement layer, the content of the aluminum element gradually decreases along the growth direction of the epitaxial wafer, and the content of the indium element gradually increases along the growth direction of the epitaxial wafer. A p-type impurity doped Al_{y}In_{1-y}P layer with the aluminum element component being y is first grown on an upper surface of the multi-quantum well layer 14, and the aluminum element component is gradually decreased from y to 0.1 by gradually reducing the flow rate of the gaseous aluminum element for reaction. Wherein, the value of y ranges from 0.3 to 0.5 or from 0.5 to 0.7. For example, a p-type impurity doped Al_{0.5}In_{0.5}P layer with the aluminum element component being 0.5 is first grown on an upper surface of the multi-quantum well layer 14, and the aluminum element component is gradually decreased from 0.5 to 0.1 by gradually reducing the flow rate of the gaseous aluminum element for reaction.

In one embodiment, the first p-type confinement layer may have a thickness of 40 nm to 50 nm, 50 nm to 60 nm, 60 nm to 70 nm, 70 nm to 80 nm, 80 nm to 90 nm, 90 nm to 100 nm, 100 nm to 110 nm or 110 nm to 120 nm.

In one embodiment, the second p-type confinement layer may have a thickness of 40 nm to 50 nm, 50 nm to 60 nm, 60 nm to 70 nm, 70 nm to 80 nm, 80 nm to 90 nm, 90 nm to 100 nm, 100 nm to 110 nm or 110 nm to 120 nm.

It should be noted that, in a specific implementation, the thickness of the first p-type confinement layer may be the same as or different from the thickness of the second p-type confinement layer.

In the present embodiment, both the n-type semiconductor layer and the p-type semiconductor layer have one layer with Al component gradually changing, and one layer with Al component being constant. For a confinement layer prepared according to this method, in cases of quaternary system red light, if there is only an AlInP confinement layer with Al component gradually changing, holes and electrons in the multi-quantum well layer still easily move to the outside of the multi-quantum well layer, an AlInP layer of a certain thickness is provided in a direction close to the multi-quantum well layer after the gradually changing component, such that a higher potential barrier can be obtained at two side of the multi-quantum well layer to block the holes and electrons from moving to the outside of the multi-quantum well layer.

As shown in FIG. 3, in one or more embodiments, the n-type semiconductor layer 13 further comprises an n-type reflection layer 132, and the n-type reflection layer 132 is an n-type Bragg reflection layer. The the n-type Bragg reflection layer may have a thickness of 500 nm to 700 nm, 700 nm to 900 nm or 900 nm to 1100 nm.

In one or more embodiments, the epitaxial wafer further comprises a buffer layer 11 and a current spreading layer 16, the buffer layer 11 is stacked below the n-type semiconductor layer 13, and the current spreading layer 16 is stacked above the p-type semiconductor layer 15.

In the present embodiment, the buffer layer 11 may be an n-type GaAs buffer layer. The buffer layer may have a thickness of 90 nm to 100 nm, 100 nm to 110 nm, 110 nm to 120 nm, 120 nm to 130 nm, 130 nm to 140 nm, 140 nm to 150 nm, 150 nm to 160 nm or 160 nm to 170 nm.

The current spreading layer 16 may be a GaP current spreading layer, and the current spreading layer may have a thickness of 1500 nm to 1700 nm, 1700 nm to 1900 nm, 1900 nm to 2100 nm, 2100 nm to 2300 nm or 2300 nm to 2500 nm.

As shown in FIG. 4, on the basis of the same inventive concept, the present application further provides a method for preparing an epitaxial wafer of a red light-emitting diode, the method comprising:

S10, providing a substrate; and

S20, sequentially growing an n-type semiconductor layer, a multi-quantum well layer and a p-type semiconductor layer on a surface of the substrate;

wherein the n-type semiconductor layer comprises a first n-type confinement layer and a second n-type confinement layer that are sequentially stacked, and in the first n-type confinement layer, the content of an aluminum element gradually increases along a stacking direction of the epitaxial wafer, and the content of an indium element gradually decreases along the stacking direction of the epitaxial wafer, and in the second n-type confinement layer, the content of an aluminum element and an indium element does not change along the stacking direction of the epitaxial wafer.

Specifically, the substrate is a gallium arsenide GaAs substrate, the substrate is cleaned and dried and then is put into a reaction chamber of a metal-organic chemical vapor deposition (MOCVD) device, the temperature of the reaction chamber is controlled, and a gaseous aluminum source and indium source are introduced into the reaction chamber, an n-type semiconductor layer is grown on a surface of the substrate, and the content of the aluminum element and the indium element in the n-type semiconductor layer is controlled by controlling the molar flow rates of the introduced aluminum source and indium source. After the preparation of the n-type semiconductor layer is completed, a multi-quantum well layer and a p-type semiconductor layer are sequentially prepared, so as to obtain an epitaxial wafer of a red light-emitting diode.

In the present embodiment, the flow rate of the gaseous aluminum source introduced into the reaction chamber is adjusted (gradually increased), an n-type confinement layer with the content of the aluminum element gradually increasing along a growth direction of the epitaxial wafer and the content of the indium element gradually decreasing along the growth direction of the epitaxial wafer is grown on the surface of the substrate, and when a predetermined thickness is reached, the flow rate of the gaseous aluminum source is adjusted to grow another n-type confinement layer of a certain thickness with the content of the aluminum element and the indium element not changing along the growth direction of the epitaxial wafer.

In some embodiments, the first n-type confinement layer is an n-type impurity doped AlₐIn₁₋ₐP layer, and the value of a gradually increases from 0.1 to x along the growth direction of the epitaxial wafer, wherein 0.3<x<0.7; and the second n-type confinement layer is an n-type impurity doped AlₓIn₁₋ₓP layer.

Specifically, the preparation method therefor may be as follows: providing a GaAs substrate, cleaning and drying the GaAs substrate and then putting same into a reaction chamber of an MOCVD device, setting the temperature of the reaction chamber to be 700° C.-850° C., and simultaneously introducing a gaseous aluminum source, indium source and phosphorus source into the reaction chamber, after aluminum Al, indium In and phosphorus P atoms are bound to each other, an AlₐIn₁₋ₐP layer being grown on a surface of the GaAs substrate, controlling the Al component a by controlling the molar flow rates of the aluminum source, the indium source and the phosphorous source, and introducing silane or diethyl telluride at the same time to form n-type doping. Wherein, the initial value of a is set to be 0.1, and the introduction amount of the aluminum source is gradually increased, such that the value of a is gradually increased from 0.1 to a preset value (for example, x), and the preset value x may be a value greater than 0.3 and less than 0.7, such as 0.4, 0.5 and 0.6. When the AlₐIn₁₋ₐP layer reaches a certain thickness of 40 nm-120 nm (for example, 80 nm), the introduction amount of the aluminum source is changed or maintained, and after a period of introduction, an AlₓIn₁₋ₓP layer is grown on the AlₐIn₁₋ₐP layer, and the AlₓIn₁₋ₓP layer may have a thickness of 40 nm-120 nm (for example, 50 nm).

Further, the n-type semiconductor layer further comprises an n-type reflection layer, and the n-type reflection layer is a DBR reflection layer. Namely, before the first n-type confinement layer is prepared, a DBR reflection layer is first grown to improve the light-emitting efficiency of an epitaxial wafer of a red LED.

In some embodiments, a buffer layer is grown between the substrate and the n-type semiconductor layer, and a current spreading layer is grown above the p-type semiconductor layer. Namely, an n-type GaAs buffer layer is grown on a surface of the GaAs substrate, the buffer layer may have a thickness of 150 nm, a GaP current spreading layer is grown above the p-type semiconductor layer, and the GaP current spreading layer may have a thickness of 2000 nm.

Further, the present application further provides a method for preparing another epitaxial wafer of a red light-emitting diode, i.e., improving the preparation of p-confinement layers on the basis of the described method for preparing an epitaxial wafer of a red light-emitting diode, specifically, designing the p-semiconductor layer as a first p-type confinement layer with the content of an aluminum element and an indium element not changing along a growth direction of the epitaxial wafer, and a second p-type confinement layer with the content of an aluminum element gradually decreasing along the growth direction of the epitaxial wafer and the content of an indium element gradually increasing along the growth direction of the epitaxial wafer.

In the present embodiment, the second p-type confinement layer is a p-type impurity doped Al_{b}In_{1-b}P layer grown on the multi-quantum well layer, and the value of b gradually decreases from y to 0.1 along the growth direction of the epitaxial wafer, wherein 0.3<y<0.7; and the first p-type confinement layer is a p-layer of p-type impurity doped Al_{y}In_{1-y}P grown on the p-type impurity doped Al_{b}In_{1-b}P layer.

The preparation method above provided in the present application will be further explained and illustrated below by means of a specific embodiment.

A GaAs substrate is provided, the GaAs substrate is cleaned and then is put into a reaction chamber of an MOCVD device, the temperature of the reaction chamber is set to be 750° C., a gaseous aluminum source, indium source and phosphorus source are simultaneously introduced into the reaction chamber, after aluminum Al, indium In and phosphorus P atoms are bound to each other, an Al_{.05}In_{0.5}P layer with a thickness of 80 nm is grown on a surface of the GaAs substrate, and then the flow rate of the introduced aluminum source is controlled to remain unchanged to grow an Al_{0.5}In_{0.5}P layer with a thickness of 60 nm, and silane or diethyl telluride is introduced at the same time to form n-type doping; and the system gas flow is switched, a multi-quantum well layer with a thickness of 450 nm is then grown on the Al_{0.5}In_{0.5}P layer, the introduced gas flow is switched to adjust the introduction amount of the aluminum source, Magnesocene is introduced at the same time to grow p-doped Al_{0.6}In_{0.4}P with a thickness of 100 nm on a surface of the multi-quantum well layer, then the flow rate of the introduced aluminum source is gradually reduced, and an Al_{0.1}In_{0.9}P layer with a thickness of 40 nm and an aluminum component from 0.6 to 0.1 is grown, the system gas source is switched to finally grow a p-type GaP current spreading layer with a thickness of 2000 nm on the Al_{0.1}In_{0.9}P layer, so as to obtain an epitaxial wafer of a red light-emitting diode.

In summary, the present application provides an epitaxial wafer of a red light-emitting diode, and a manufacturing method therefor, an n-type semiconductor layer is designed as a gradient layer with the content of an aluminum element gradually increasing along a growth direction of the epitaxial wafer and the content of an indium element gradually decreasing along a stacking direction of the epitaxial wafer, and a constant layer with the content of an aluminum element and an indium element not changing along the growth direction of the epitaxial wafer, and a p-type semiconductor layer is designed as a constant layer with the content of an aluminum element and an indium element not changing along the growth direction of the epitaxial wafer and a gradient layer with the content of an aluminum element gradually decreasing along the growth direction of the epitaxial wafer and the content of an indium element gradually increasing along the stacking direction of the epitaxial wafer, confining holes and electrons to have a radiative recombination in a multi-quantum well layer and reducing non-radiative recombination. In addition, the design of enabling the potential barrier at two sides of the multi-quantum well layer to gradually rise also facilitates the flowing of electrons in the n-type semiconductor layer and holes in the p-type semiconductor layer to the multi-quantum well layer region, further increasing the number of photons flowing to the multi-quantum well layer region for recombination, thus improving the light-emitting efficiency.

It should be understood that the application of the present application is not limited to the examples above, and those skilled in the art can make improvements or modifications according to the above descriptions, and all these improvements and modifications shall belong to the scope of protection of the appended claims of the present application.

What is claimed is:

1. An epitaxial wafer of a red light-emitting diode, comprising: an n-type semiconductor layer, a multi-quantum well layer and a p-type semiconductor layer that are sequentially stacked;
the n-type semiconductor layer comprises a first n-type confinement layer and a second n-type confinement layer;
the first n-type confinement layer comprises an aluminum element and an indium element, and the second n-type confinement layer comprises an aluminum element and an indium element; and
the content of the aluminum element of the first n-type confinement layer gradually increases along a growth direction of the epitaxial wafer, and the content of the indium element of the first n-type confinement layer gradually decreases along the growth direction of the epitaxial wafer; and the content of the aluminum element of the second n-type confinement layer and the indium element of the second n-type confinement layer does not change along the growth direction of the epitaxial wafer.

2. The epitaxial wafer of a red light-emitting diode according to claim 1, wherein the first n-type confinement layer is an n-type impurity doped AlaI1-aP layer, and the value of a gradually increases from 0.1 to x along the growth direction of the epitaxial wafer, wherein 0.3<x<0.7.

3. The epitaxial wafer of a red light-emitting diode according to claim 2, wherein the second n-type confinement layer is an n-type impurity doped AlxIn1-xP layer.

4. The epitaxial wafer of a red light-emitting diode according to claim 1 wherein the first n-type confinement layer has a thickness of 40 nm-120 nm.

5. The epitaxial wafer of a red light-emitting diode according to claim 1, wherein the thickness of the first n-type confinement layer is the same as the thickness of the second n-type confinement layer.

6. The epitaxial wafer of a red light-emitting diode according to claim 1, wherein the p-type semiconductor layer comprises a first p-type confinement layer and a second p-type confinement layer that are sequentially stacked; the first p-type confinement layer comprises an aluminum element and an indium element, and the second p-type confinement layer comprises an aluminum element and an indium element; and the content of the aluminum element of the first p-type confinement layer and the indium element of the first p-type confinement layer does not change along the growth direction of the epitaxial wafer, and the content of the aluminum element of the second p-type confinement layer gradually decreases along the growth direction of the epitaxial wafer, and the content of the indium element of the second p-type confinement layer gradually increases along the growth direction of the epitaxial wafer.

7. The epitaxial wafer of a red light-emitting diode according to claim 6, wherein the second p-type confinement layer is a p-type impurity doped AlbIn1-bP layer, and the value of b gradually decreases from y to 0.1 along the growth direction of the epitaxial wafer, wherein 0.3<y<0.7.

8. The epitaxial wafer of a red light-emitting diode according to claim 7, wherein the first p-type confinement layer is a p-layer of p-type impurity doped AlyIn1-yP.

9. The epitaxial wafer of a red light-emitting diode according to claim 8, wherein the first p-type confinement layer has a thickness of 40 nm-120 nm.

10. The epitaxial wafer of a red light-emitting diode according to claim 1, wherein the n-type semiconductor layer further comprises an n-type reflection layer, and the n-type reflection layer is an n-type Bragg reflection layer.

11. The epitaxial wafer of a red light-emitting diode according to claim 1, wherein the epitaxial wafer further comprises a buffer layer and a current spreading layer, the buffer layer is stacked below the n-type semiconductor layer, and the current spreading layer is stacked above the p-type semiconductor layer.

12. A method for preparing an epitaxial wafer of a red light-emitting diode, wherein the method comprises:
providing a substrate; and
sequentially growing an n-type semiconductor layer, a multi-quantum well layer and a p-type semiconductor layer on a surface of the substrate;
wherein the n-type semiconductor layer comprises a first n-type confinement layer and a second n-type confinement layer that are sequentially stacked, and the content of an aluminum element of the first n-type confinement layer gradually increases along a stacking direction of the epitaxial wafer, and the content of an indium element of the first n-type confinement layer gradually decreases along the stacking direction of the epitaxial wafer, and the content of an aluminum element of the second n-type confinement layer and an indium element of the second n-type confinement layer does not change along the stacking direction of the epitaxial wafer.

13. The method for preparing an epitaxial wafer of a red light-emitting diode according to claim 12, wherein growing an n-type semiconductor layer on a surface of the substrate specifically comprises:
controlling a molar flow rate of introduced gaseous aluminum to grow an n-type impurity doped AlaIn1-aP layer on the substrate, the value of a gradually increasing from 0.1 to x along a growth direction of the epitaxial wafer, wherein 0.3<x<0.7; and
growing an n-type impurity doped AlxIn1-xP layer on the n-type impurity doped AlaIn1-aP layer.

14. The method for preparing an epitaxial wafer of a red light-emitting diode according to claim 13, wherein the n-type impurity doped AlxIn1-xP layer has a thickness of 40 nm-120 nm.

15. The method for preparing an epitaxial wafer of a red light-emitting diode according to claim 12, wherein the n-type semiconductor layer further comprises an n-type reflection layer, and the n-type reflection layer is grown below the first n-type confinement layer.

16. The method for preparing an epitaxial wafer of a red light-emitting diode according to claim 15, wherein the n-type reflection layer is an n-type Bragg reflection layer.

17. The method for preparing an epitaxial wafer of a red light-emitting diode according to claim 12, wherein a buffer layer is grown between the substrate and the n-type semiconductor layer, and a current spreading layer is grown above the p-type semiconductor layer.

18. The method for preparing an epitaxial wafer of a red light-emitting diode according to claim 12, wherein the p-type semiconductor layer comprises a first p-type confinement layer and a second p-type confinement layer that are sequentially stacked; the first p-type confinement layer comprises an aluminum element and an indium element, and the second p-type confinement layer comprises an aluminum element and an indium element; and the content of the aluminum element of the first p-type confinement layer and the indium element of the first p-type confinement layer does not change along the growth direction of the epitaxial wafer, and the content of the aluminum element of the second p-type confinement layer gradually decreases along the growth direction of the epitaxial wafer, and the content of the indium element of the second p-type confinement layer gradually increases along the growth direction of the epitaxial wafer.

19. The method for preparing an epitaxial wafer of a red light-emitting diode according to claim 17, wherein growing a p-type semiconductor layer on a surface of the multi-quantum well layer specifically comprises:
controlling a molar flow rate of introduced gaseous aluminum to grow a p-type impurity doped AlyIn1-yP layer on the multi-quantum well layer, wherein 0.3<y<0.7; and
growing a p-layer of a p-type impurity doped AlbIn1-bP layer on the p-type impurity doped AlyIn1-yP layer, the value of b gradually decreasing from y to 0.1 along the growth direction of the epitaxial wafer.

20. The method for preparing an epitaxial wafer of a red light-emitting diode according to claim 18, wherein the p-layer of a p-type impurity doped AlyIn1-yP layer has a thickness of 40 nm-120 nm.
